(19) United States
(12) Patent Application Publication
(10) Pub. No.: US 2013/0168823 A1
(43) Pub. Date: Jul. 4, 2013

(54) SYSTEMS AND METHODS FOR BACKSIDE THRESHOLD VOLTAGE ADJUSTMENT

(71) Applicant: Ryosuke Iijima, Albany, NY (US)

(72) Inventor: Ryosuke Iijima, Albany, NY (US)

(73) Assignee: TOSHIBA AMERICA ELECTRONIC COMPONENTS, INC., Irvine, CA (US)

(21) Appl. No.: 13/338,478

(22) Filed: Dec. 28, 2011

(51) Int. Cl. H01L 29/36; H01L 21/265

(52) U.S. Cl. 257/607; 438/517; 257/E29.109; 257/E21.334

(57) ABSTRACT

Described herein are semiconductor devices with a threshold voltage (Vₜ) adjusted through back gate stack engineering to meet performance and power requirements and corresponding back gate stack engineering methods. The semiconductor devices can include a thin SOI region, a thin BOX region and a semiconductor substrate. The threshold voltage can be adjusted in the backside of the semiconductor device through implantation of one or more dopants into the BOX region such that the peak concentration of the one or more dopants is inside the BOX region.

### FIELD

Embodiments described herein generally relate to semiconductor devices with a threshold voltage adjusted through back gate stack engineering and corresponding back gate stack engineering methods.

### BACKGROUND

Recent trends in electronics have required smaller devices with larger computational capabilities. This has required a steady reduction in the size of semiconductor devices to accommodate a large integration density of semiconductor devices to achieve performance and power requirements of such computational capabilities.

One such semiconductor device is an ultra thin body and box (UTBB) fully-depleted (FD) silicon-on-insulator (SOI)-MOSFET (metal oxide semiconductor field effect transistor). The UTBB FD SOI-MOSFET is a structure where a semiconductor layer is formed above SOI layer, formed above a BOX insulator layer, which is formed on a semiconductor substrate. UTBB SOI-MOSFETs exhibit a thin SOI region and a thin BOX region.

### BRIEF DESCRIPTION OF DRAWINGS

FIG. 1 is a cross-sectional schematic illustration of an example UTBB SOI-MOSFET.

FIG. 2 is a process flow diagram of a method for back gate stack engineering.

FIG. 3 is a plot validating the method for back gate stack engineering.

FIG. 4 is a plot validating the method for back gate stack engineering.

FIG. 5 is a cross-sectional schematic illustration of a semiconductor device with an implantation region.

FIG. 6 is a cross-sectional illustration of a semiconductor device with an example implantation region.

FIG. 7 is a cross-sectional illustration of a semiconductor device with an example implantation region.

FIG. 8 is a cross-sectional illustration of a semiconductor device with an example implantation region.

FIG. 9 is a cross-sectional illustration of a semiconductor device that can also undergo implantation.

### DETAILED DESCRIPTION

The subject innovation generally relates to tuning the threshold voltage (Vₜ) of a semiconductor device to meet performance and power requirements. An example of such a semiconductor device is an UTBB device with a thin SOI region and a thin BOX region. The threshold voltage can be adjusted in the back side of a UTBB device through implantation of one or more dopants into the BOX region such that the peak concentration of the one or more dopants exists inside the BOX region. The peak concentration can be (1) at the bottom interface between the BOX region and the back gate electrode, (2) in the bulk of the BOX region and/or (3) at the front interface between the SOI region and the BOX region, as long as the peak concentration is within the BOX region. This back gate stack engineering by implanting one or more dopants in the BOX region can facilitate the adjustment of the threshold voltage to optimize performance of the semiconductor device.

The subject innovation is now described with reference to the drawings, wherein like reference numerals are used to refer to like elements throughout. In the following description, for purposes of explanation, numerous specific details are set forth in order to provide a thorough understanding of the subject innovation. It may be evident, however, that the subject innovation may be practiced without these specific details. In other instances, well-known structures and devices are shown in block diagram form in order to facilitate describing the subject innovation.

With respect to any figure or numerical range for a given characteristic, a figure or a parameter from one range may be combined with another figure or a parameter from a different range for the same characteristic to generate a numerical range.

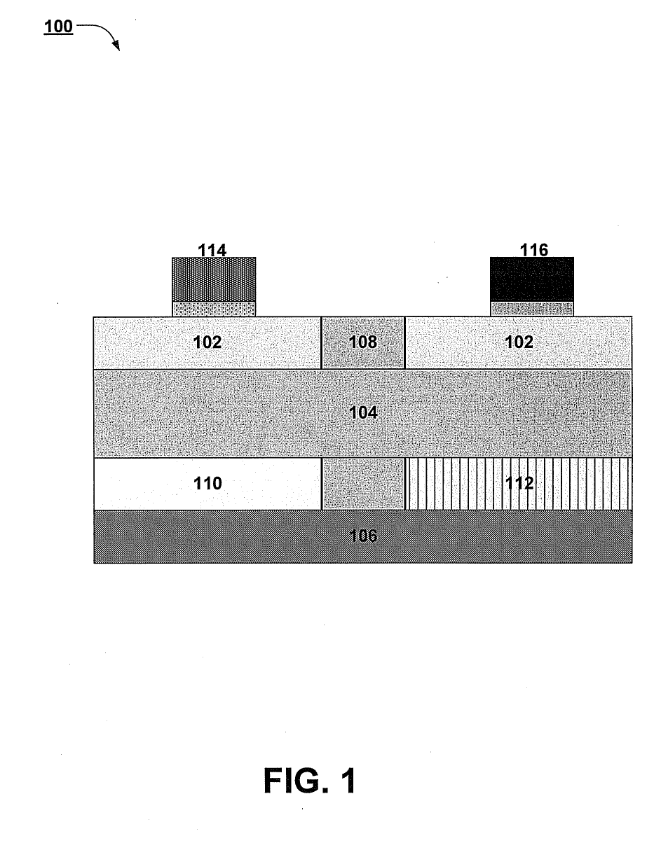

Referring now to FIG. 1, illustrated is a cross-sectional schematic illustration of an example UTBB fully depleted SOI-MOSFET 100 (or UTBB device). The UTBB device includes an extremely thin silicon on insulator region (ET-SOI) 102. The ET-SOI region can have a thickness of about 10 nm or less. SOI refers to the use of a layered silicon-insulator-silicon substrate in place of a conventional silicon substrate to reduce parasitic device capacitance and thereby improve performance.

The UTBB device 100 also includes a thin buried oxide (BOX) region 104, which can act as an insulator. The thin BOX region 104 can include a metal or metalloid oxide. The BOX region can include two natural elements, such as silicon and oxygen. The thin BOX region 104 can have a thickness of about 30 nm or less. The ET-SOI region is formed on thin BOX region 104, which is formed on a semiconductor substrate 106.

Semiconductor substrate 106 can be an i-type semiconductor. An i-type semiconductor can also be referred to as an intrinsic semiconductor or an undoped semiconductor. In other words, an i-type semiconductor is any pure semiconductor without any significant dopant species present. A high concentration of impurities can be introduced into the semiconductor substrate 106. The semiconductor substrate and the associated gates 110 and 112 can be controlled as a backside electrode independent from a top gate electrode (not illustrated). When used herein, “backside” refers to the back side of the ET-SOI region.

The UTBB device 100 also includes a shallow trench isolation (STI) region 108. STI, also known as the BOX isolation technique, is utilized to prevent electrical current leakage between adjacent semiconductor device components.

The UTBB device 100 also includes back gates 110 and 112 that are formed on the semiconductor substrate 106. The back gates can includes an N+back gate 110 and a P+ back gate 112. The UTBB device 100 can also include two gate stacks 116 and 118. Integration of gate stacks 116 and 118 can complicate the manufacturing of the UTBB device 100. Separation of the back gate electrode can simplify the manufacturing process. However, even an incomplete separation of the back gate electrode limits the range of motion of the back gate bias, so it becomes difficult to the adjust threshold voltage. Implanting a dopant or dopants into the BOX region 104 can spread the range of motion of the back gate bias and facilitate control of the threshold voltage of the back gate channel.

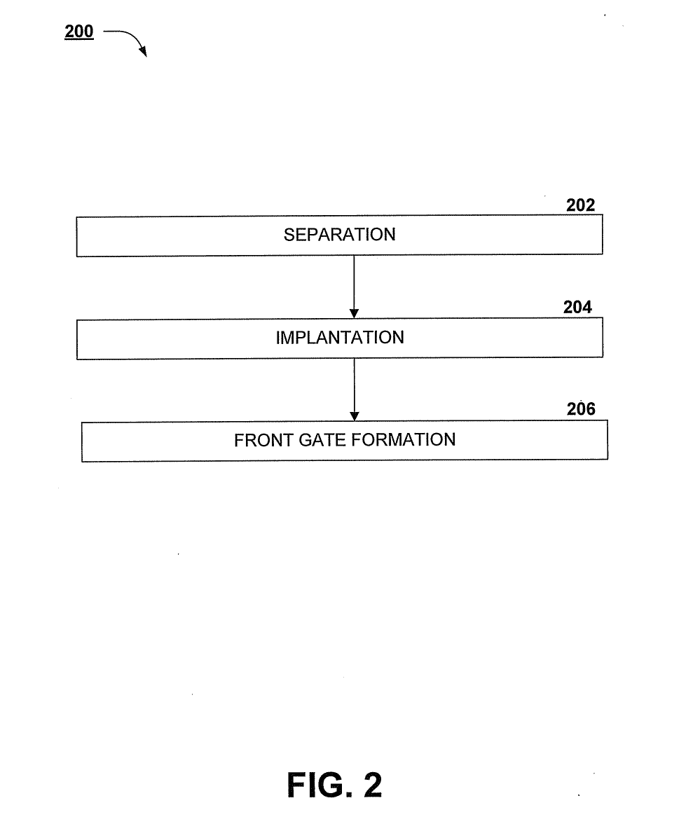

Referring now to FIG. 2, illustrated is a process flow diagram of a method 200 for back gate stack engineering of a semiconductor device. The semiconductor device can be any semiconductor device that includes a SOI region, a BOX region and a semiconductor substrate. The semiconductor device can also include a back gate stack.

At element 202, the back gate stack can be separated and/or pieced from the semiconductor device. This separation of the back gate stack can generate a charge on the backside of the SOI layer. At element 204, the BOX region can be implanted with a “third element” referred to as a dopant. The dopant can be any element different than the metal or metalloid oxide of the BOX region. In other words, when the BOX region includes Si and O, the dopant can be any element other than Si and O. Depending on the application and/or desired characteristics of the semiconductor device, one or more dopants can be chosen from different categories. The one or more dopants can be selected from a category that includes the following elements: N, F, Cl, Ge, and C. The dopant can also be selected from a category that includes the following elements: In, As, Ga, and P. The dopant can also be selected from a category that includes the following elements: Hf, Zr, La, Al, Sc, Sr, Ce, Ti, Lu, Dy and Y.

The implantation method can be chosen according to the specific dopant element or elements. While one implantation technique can implant elements, such as N, F, Cl or Ge, the same implantation technique may not be able to implant elements, such as Hf, Zr, La, Al, Sc, Sr, Ce, Ti, Lu, Dy and Y. The implantation method can be any implantation method that can facilitate the implantation of the chosen dopant element into the BOX region.

The implantation method is constrained in that the peak dopant concentration must exist within the BOX region. The peak dopant concentration is defined according to a concentration profile for the dopant across the semiconductor device. A dopant concentration can exist in areas of the semiconductor device either naturally or through methods like diffusion after implantation. However, the highest concentration of the dopant must exist in the BOX region. In other words, when examining a concentration profile for the dopant across the entire semiconductor device, the peak of the concentration profile must exist in the BOX region.

The dopant can exist within the semiconductor device, and the BOX region, naturally without implantation. The implantation is an intentional addition of the dopant into the BOX region. Accordingly, the concentration profile for the dopant in the semiconductor device can be non-zero. However, the peak concentration should be in the BOX region of the semiconductor device to show intentional implantation greater than the natural level.

The peak concentration of the dopant is generally greater than or equal to the natural or baseline concentration level of the dopant in the semiconductor device and less than or equal to the peak concentration of Si in the semiconductor device. The peak concentration of the dopant is an amount of dopant that is sufficient to adjust the threshold voltage in the backside to a desired level, which can vary based on the applications of the semiconductor device.

Generally, as the peak concentration of the dopant increases, the threshold voltage also increases. For different applications, different threshold voltages are considered optimal. The peak dopant concentration can be adjusted so that the semiconductor device can exhibit the optimal threshold voltage for a desired application.

After the dopant implantation 204, at element 206, the front gate can be formed. The implantation occurs at the backside for control of the backside threshold voltage.

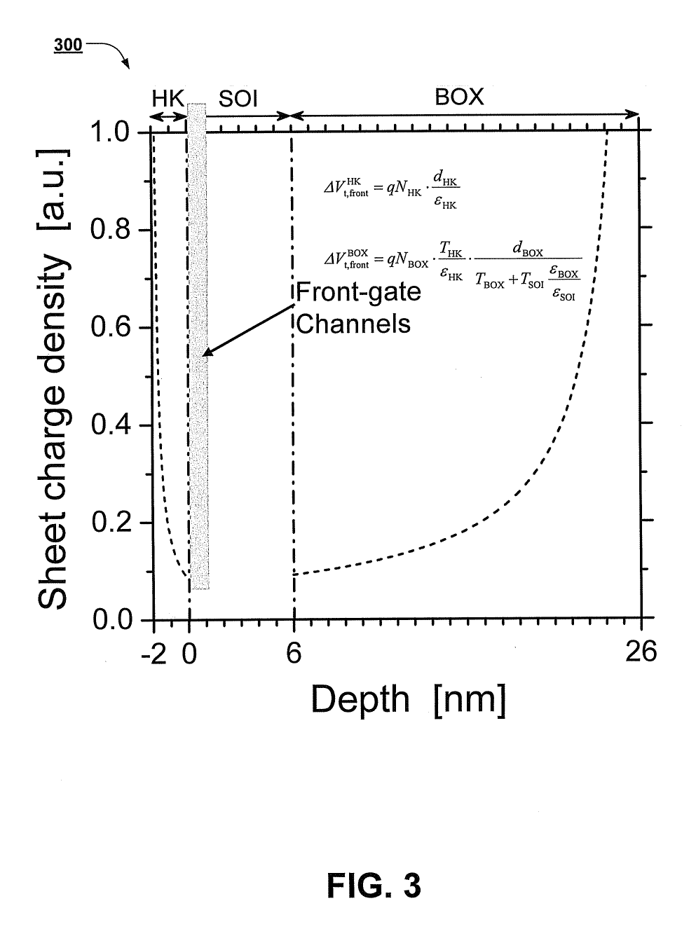

A comparison between the front gate stack and the back gate stack is shown in FIG. 3. As shown in plot 300, the back gate stack is of a greater thickness than the front gate stack. In plot 300, the front gate stack is the highlighted portion, while the back gate stack includes the SOI region and the BOX region. According to the example shown in plot 300, the thickness of front gate stack can be on the order of 1 nm, while the thickness of the SOI region can be on the order of 6 nm and the thickness if the BOX region can be on the order of 20 nm.

Plot 300 shows the sheet charge density for various depths in the back gate region. A voltage drop and or shift can exit if the back gate stack has a small amount of fixed charge, event distant from the channel. Therefore, a charge shift induced by implantation can cause a shift in threshold voltage, even if the peak concentration is distant from the front gate channels.

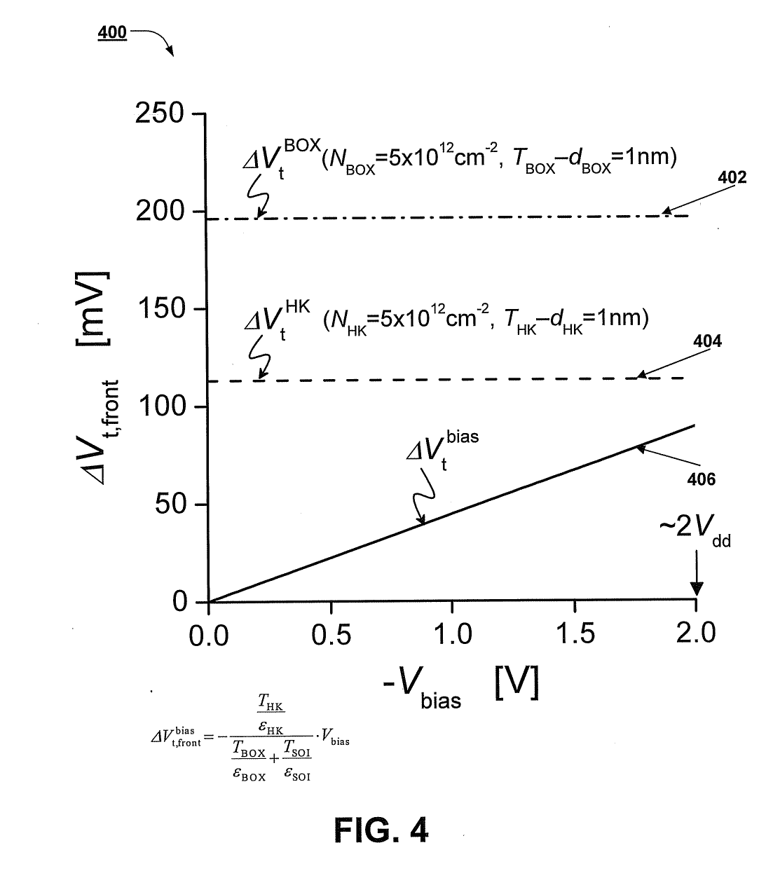

FIG. 4 illustrates a comparison of bias effect and the backside electrode, using the same dimensions as FIG. 3. In terms of threshold voltage adjustment, the BOX with internal charge generation compares favorably to the back electrode bias.

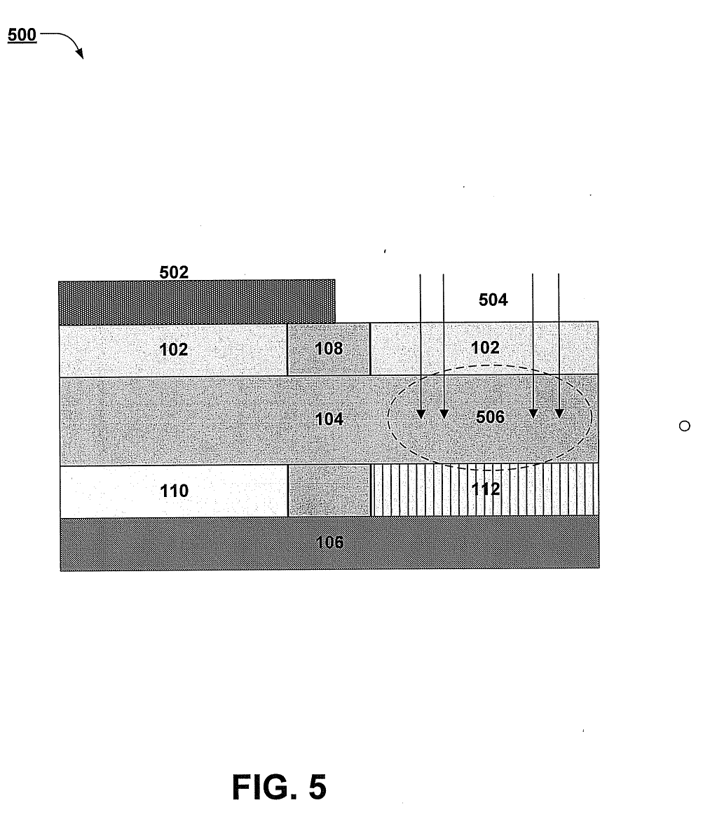

Referring now to FIG. 5, illustrated is a cross-sectional schematic illustration 500 of a semiconductor device, such as a UTBB SOI-MOSFET, that has undergone the implantation method illustrated in FIG. 2. The semiconductor device can be any semiconductor device includes a SOI region 102, a BOX region 104 and a semiconductor substrate 106.

The back gate stack 502 has been separated and/or pieced from the semiconductor device. This allows charge to be generated on the backside of the SOI layer and facilitates the backside implantation 504.

The implantation 504 is a process by which a dopant is implanted into the BOX region 104. The dopant can, be any element different than the metal or metalloid oxide of the BOX region 104. For example, the dopant can be any element other than Si and 0 when the BOX region 104 includes Si and O.

Depending on the application and/or desired characteristics of the semiconductor device 500 and/or the annealing process utilized, one or more dopants can be chosen from different categories. The one or more dopants can be selected from a category that includes the following elements: N, F, Cl, Ge, and C. The dopant can also be selected from a category that includes the following elements: In, As, Ga, and P. The dopant can also be selected from a category that following elements: Hf, Zr, La, Al, Sc, Sr, Ce, Ti, Lu, Dy and Y.

The implantation method can be chosen according to the specific dopant element or elements. While one implantation technique can implant elements, such as N, F, Cl or Ge, the same implantation technique may not be able to implant elements, such as Hf, Zr, La, Al, Sc, Sr, Ce, Ti, Lu, Dy and Y. The implantation method can be any implantation method that can facilitate the implantation of the chosen dopant element into the BOX region.

The implantation method is constrained in that the peak dopant concentration 506 must exist within the BOX region 104. The peak dopant concentration 506 is defined according to a concentration profile for the dopant across the semiconductor device 500. A dopant concentration can exist in areas of the semiconductor device 500 either naturally or through methods like diffusion after implantation. However, the highest concentration of the dopant must exist in the BOX region 104. In other words, when examining a concentration profile for the dopant across the entire semiconductor device 500, the peak of the concentration profile must exist in the BOX region 104.

The dopant can exist within the semiconductor device 500, and the BOX region 104, naturally without implantation. The implantation is an intentional addition of the dopant into the BOX region 104. Accordingly, the concentration profile for the dopant in the semiconductor device 500 can be non-zero. However, the peak concentration 506 should be in the BOX region 104 of the semiconductor device 500 to show intentional implantation greater than the natural level.

The peak concentration of the dopant 506 is generally greater than or equal to the natural or baseline concentration level of the dopant in the semiconductor device 500 and less than or equal to the peak concentration of Si in the semiconductor device 500. The peak concentration of the dopant 506 is an amount of dopant that is sufficient to adjust the threshold voltage in the backside to a desired level, which can vary based on the applications of the semiconductor device 500.

Generally, as the peak concentration of the dopant 506 increases, the threshold voltage also increases. For different applications, different threshold voltages are considered optimal. The peak dopant concentration 506 can be adjusted so that the semiconductor device 500 can exhibit the optimal threshold voltage for a desired application.

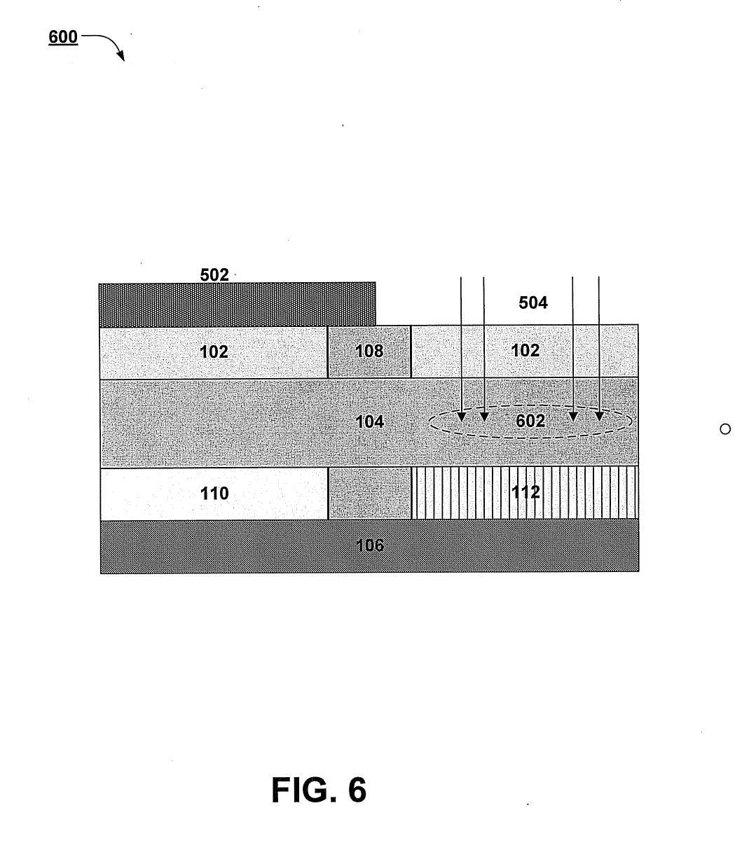

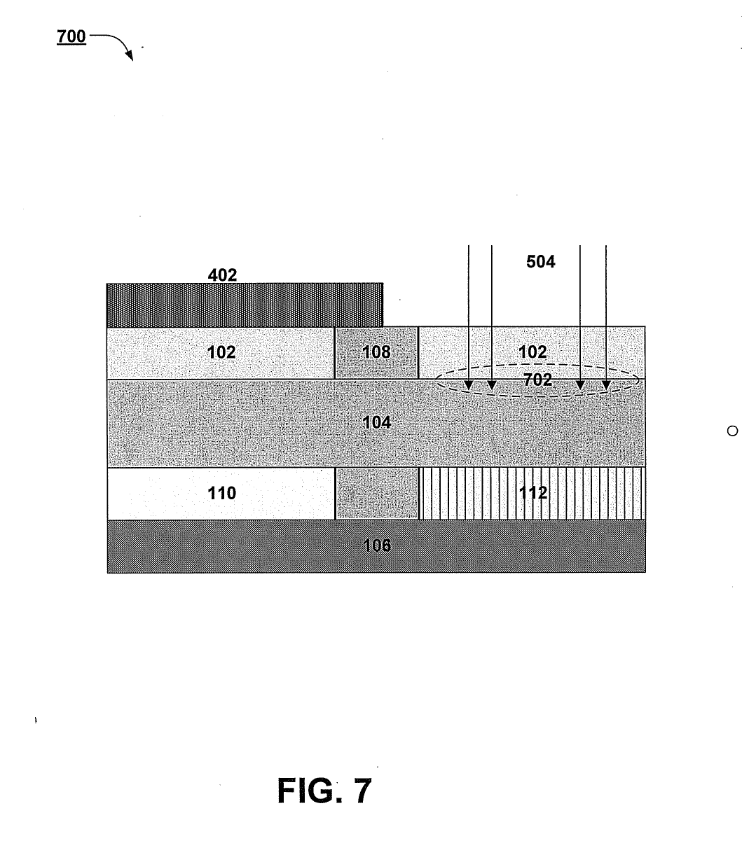

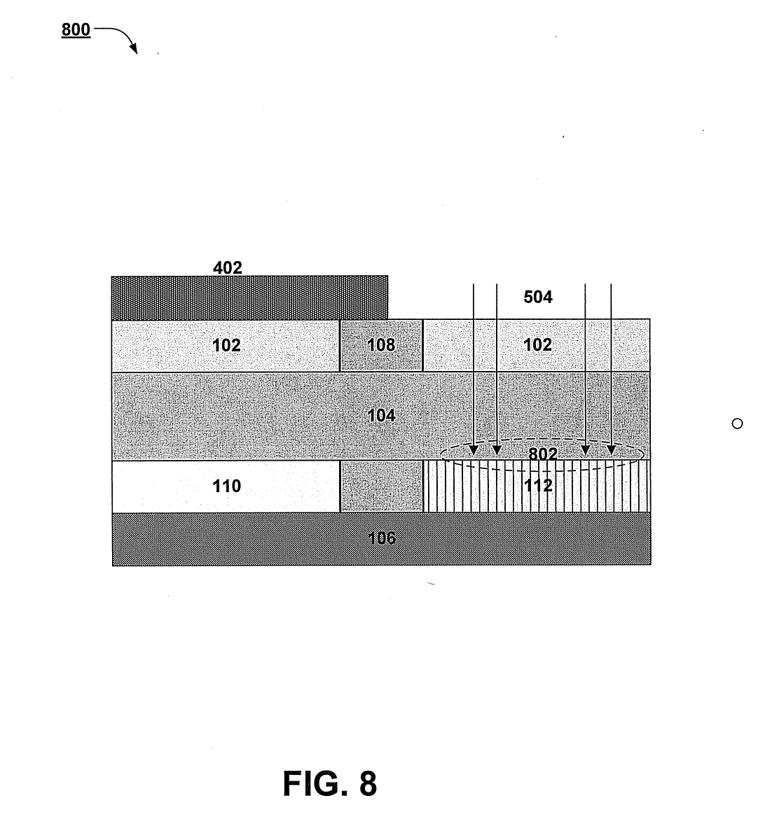

As illustrated in FIGS. 6-8, the peak dopant concentration 602-802 can be located in different areas of the BOX region 104. As illustrated in FIG. 6, the peak dopant concentration 602 can be located in the bulk internal to the BOX. As illustrated in FIG. 7, the peak dopant concentration 702 can be located at the back channel interface between the SOI region 102 and the BOX region 104. As illustrated in FIG. 8, the peak dopant concentration can be located at the back gate interface between the BOX region 104 and the back gate 112. In each case 600-800, the peak dopant concentration 602-604 is still located within the BOX region 104.

Different elements can be used as dopants for the different areas of peak concentration 602-802. When the peak dopant concentration 602 is located in the bulk area of the BOX region 104 to create a fixed charge, elements that are preferable to implant include N, F, Cl, Ge, and C. Of this group N and F are preferable.

When the peak dopant concentration 702 is located in the boundary region between the SOI region 102 and the BOX region 104 to produce a fixed charge, elements that are preferable to include are In, As, Ga, and P. Ideally, these elements can pile-up in self alignment. Of these elements, Ge is preferable.

When the peak dopant concentration is located at the interface between the BOX region 104 and the back gate 112, elements that are preferable to implant include Hf, Zr, La, Al, Sc, Sr, Ce, Ti, Lu, Dy and Y. Of these elements, Al is preferable. Ideally, these elements can produce a dipole due to high surface density of the metal oxide submonolayer.

In the embodiments 600 and 700, the elements can be chosen based on the ability of the implanted element to reach the back gate 112 in the BOX region 104. However, in embodiment 800, the elements can be chosen based on ability to generate a dipole

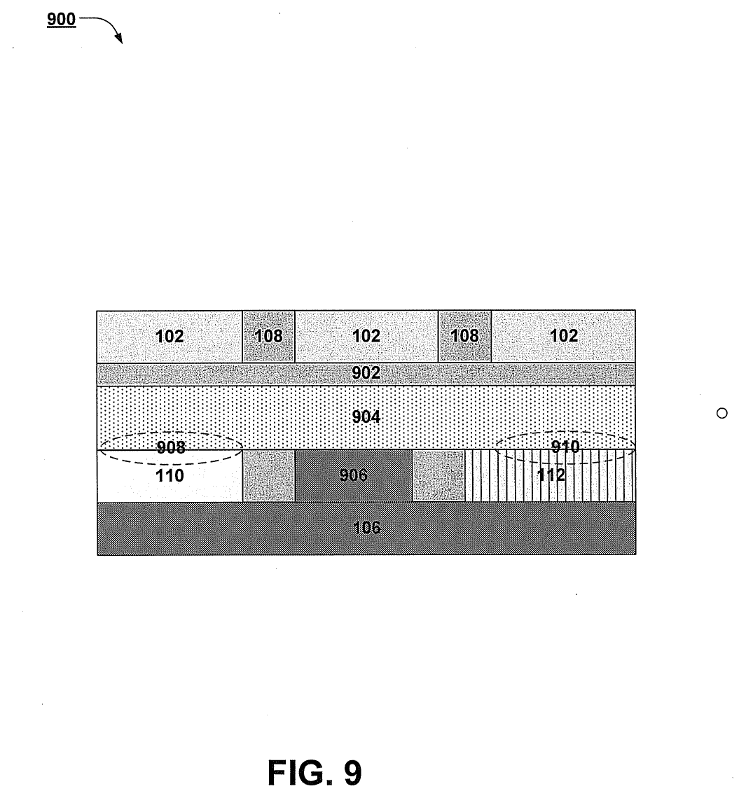

Referring now to FIG. 9, illustrated is another example of a semiconductor device 900 that can undergo implantation. In this case, the threshold voltage is independent of the back structure and the dielectric. The back gate interface is a lead weight on the dipole.

The device has a SiO₂ layer 902 and a high-k dielectric material 904. The device uses an i-type material 906 for the depletion state. The threshold voltage is independent of the back structure and the dielectric. Pining regions 908 and 910 can be created based on the deposition of the high-k material 904. This can affect threshold voltage. Implantation of a dopant in the high-k dielectric 904 can stabilize the threshold voltage and/or create better dielectrics.

Other than in the operating examples, or where otherwise indicated, all numbers, values and/or expressions referring to quantities of ingredients, reaction conditions, etc., used in the specification and claims are to be understood as modified in all instances by the term “about.”

While certain embodiments have been described, these embodiments have been presented by way of example only, and are not intended to limit the scope of the inventions. Indeed, the methods and devices described herein can be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the subject innovation.

What is claimed is:

1. A semiconductor device, comprising:
a silicon on insulator (SOI) region;
a buried oxide (BOX) region implanted with a dopant; and
a semiconductor substrate,
wherein a peak of concentration of the dopant exists within the BOX region.

2. The semiconductor device of claim 1, wherein the dopant comprises at least one of N, F, Cl, Ge, and C.

3. The semiconductor device of claim 1, wherein the dopant comprises at least one of In, As, Ga, and P.

4. The semiconductor device of claim 1, wherein the dopant comprises at least one of Hf, Zr, La, Al, Sc, Sr, Ce, Ti, Lu, Dy and Y.

5. The semiconductor device of claim 1, wherein the peak concentration of the dopant exists in the bulk of the BOX region.

6. The semiconductor device of claim 1, wherein the peak concentration of the dopant exists in the BOX region at an interface between the BOX region and the SOI region.

7. The semiconductor device of claim 1, wherein the peak concentration of the dopant exists in the BOX region at an interface between the BOX region and the semiconductor substrate.

8. The semiconductor device of claim 1, wherein the SOI region has a thickness of about 10 nm or less and the BOX region has a thickness of about 30 nm or less.

9. A method for tuning a threshold voltage at a backside of a semiconductor device comprising at least two gate stacks, a silicon on oxide (SOI) region, a buried oxide (BOX) region and a semiconductor substrate, the method comprising:
separating a gate stack from a the semiconductor device and generating a charge on the backside;
implanting a dopant in the BOX region so that a peak of concentration of the dopant exists within the BOX region; and
forming a front gate electrode.

10. The method of claim 9, wherein the dopant comprises at least one of N, F, Cl, Ge, and C.

11. The method of claim 9, wherein the dopant comprises at least one of In, As, Ga, and P.

12. The method of claim 9, wherein the dopant comprises at least one of Hf, Zr, La, Al, Sc, Sr, Ce, Ti, Lu, Dy and Y.

13. The method of claim 9, wherein the peak concentration of the dopant exists in the bulk of the BOX region.

14. The method of claim 9, wherein the peak concentration of the dopant exists in the BOX region at an interface between the BOX region and the SOI region.

15. The method of claim 9, wherein the peak concentration of the dopant exists in the BOX region at an interface between the BOX region and the semiconductor substrate.

16. The method of claim 9, wherein the SOI region has a thickness of about 10 nm or less and the BOX region has a thickness of about 30 nm or less.

17. A manufacturing method, comprising:
implanting a dopant in a backside of an insulator layer of a semiconductor device, wherein a peak concentration of the dopant is in the insulator layer; and
tuning a threshold voltage of the semiconductor device to meet a performance requirement.

18. The method of claim 17, wherein the dopant comprises at least one of N, F, Cl, Ge, and C.

19. The method of claim 17, wherein the dopant comprises at least one of In, As, Ga, and P.

20. The method of claim 17, wherein the dopant comprises at least one of Hf, Zr, La, Al, Sc, Sr, Ce, Ti, Lu, Dy and Y.
